(19) United States
(12) Patent Application Publication
(10) Pub. No.: US 2015/0075425 A1
(43) Pub. Date: Mar. 19, 2015

(54) Coating System Using Spray Nozzle

(71) Applicant: Enjet Co., Ltd., Gyeonggi-do (KR)

(72) Inventors: Do-Young Byun, Seoul (KR); Vu Dat Nguyen, Gyeonggi-do (KR); Baek Hoon Seong, Gyeongsangbuk-do (KR)

(73) Assignee: Enjet Co., Ltd., Gyeonggi-do (KR)

(21) Appl. No.: 14/226,933

(22) Filed: Mar. 27, 2014

(30) Foreign Application Priority Data
Sep. 13, 2013 (KR) 10-2013-0110716

(51) Int. Cl. C23C 16/50

(52) U.S. Cl. CPC C23C 16/50
USPC 118/708; 118/723 MP

(57) ABSTRACT

Provided herein is a coating system using a spray nozzle, the coating system comprising: a support where a substrate is disposed; a spray nozzle configured to inject towards the substrate liquid that has gone through a primary atomization by collision with gas; a voltage applier configured to apply voltage to the spray nozzle so that the liquid injected from the spray nozzle includes electric charge, and to generate an electric field between the support and the spray nozzle by the voltage applied to the spray nozzle and perform a secondary atomization of the liquid injected from the spray nozzle; and a transferrer configured to transfer at least one of the support and the spray nozzle.

### CROSS-REFERENCE TO RELATED APPLICATIONS

This application claims the benefit of priority under 35 U.S.C. §119(a) of Korean Patent Application No. 10-2013-0110716, filed on Sep. 13, 2013, in the Korean Intellectual Property Office, the entire disclosure of which is incorporated herein by reference for all purposes.

### BACKGROUND

1. Field

The following description relates to a coating system using a spray nozzle, and more particularly to a spray nozzle capable of effectively coating a substrate through droplets of a uniform size and applicable to mass production processes, and a coating system thereof.

2. Description of Related Art

A coating process is essential in not only traditional industrial areas such as automobile and construction, but also in manufacturing areas such as display and solar cell etc. Especially, when manufacturing displays such as organic solar cells and organic light emitting diodes (OLED) etc., there is required a precise coating of a thickness of tens to hundreds nanometers. In addition, since the roughness and uniformity of a coating surface have a significant effect on the performance of a product, it should be possible to use ultrafine droplets, and to coat the product quickly for mass production.

Recently, as application of touch screens increases, anti-fingerprint coating or anti-reflecting coating method for application on the surfaces of touch window surfaces such as smart phones, tablets, notebook computers etc. are being converted into wet coating processes instead of conventional vacuum coating processes.

The technology of atomizing liquid for conventional spray coating processes may be broadly classified into methods using pressure energy, gas energy, centrifugal energy, mechanical energy, and electrical energy.

Herein, the method of using pressure energy is a method of using pressure injection valves, wherein the liquid to be atomized is passed through single hole or porous injection nozzles, or vortex injection valves (simplex, duplex, dual orifice, and reflux types etc.) to form spray. This is a method generally used to spray liquid fuel injected into a gas turbine burner, randomly creating droplets of approximately 20˜250 μm. Therefore, in such a method of using pressure energy, there is a problem that it is difficult to be applied to a complicated coating technology.

In addition, the method that uses centrifugal energy utilizing a wheel atomizer or rotary cup atomizer is a method of randomly creating droplets of a range of 10˜200 μm. It is a method mainly used in cleaning and agriculture areas. In this method, it is impossible to coat the central portion, and thus there is a problem that it is difficult to be applied to a uniform coating technology.

Meanwhile, there is a gas bombardment atomizer method which is method of using gas energy, wherein a great quantity of gas in a low speed and low pressure state is injected towards a jet of liquid that is being injected using a two-fluid injection valve to atomize the liquid, and a gas assisted atomizer method wherein a small amount of gas in a high speed state is injected towards a liquid jet. This method is mainly used in thin film wet coating, but in this method, the droplets would be formed to have a random size between 15˜200 μm, thus making it difficult to form a fine thin film coating, and stains may occur on the coating surface, and further, due to the high fluid speed when injecting the gas at a high speed, the fast fluid speed may make the atomized droplets collide with the substrate, causing the droplets to bounce back. In addition, there may be too much coating liquid coming off the substrate, causing a waste of the coating liquid, thereby increasing manufacturing costs, and since the viscosity of the liquid that can be used is limited to less than 50 cp, there may be limitations in the coating technology in developing or applying functional materials, causing difficulty in developing various types of coating technologies.

Furthermore, the most representative method of using mechanical energy is the ultrasound spray technology wherein liquid is atomized by high frequency signals applied by a piezoelectric actuator. In this method, droplets may be further atomized than when using gas energy, but droplets are formed to have a random size between 1˜200 μm, making it difficult to secure uniformity in the size of droplets, and there is also a limitation in the amount of injection of droplets, thereby causing a problem of difficulty in utilizing in mass production processes.

Meanwhile, as a method of using electrical energy, there is the electrospray method wherein droplets are drawn towards a strong electric field and then atomized. An advantage of this method is that it is possible to produce fine and uniform droplets having a size range of hundreds nm to 5 μm. However, there are limitations that there needs to be at least 10⁻⁴ S/m of electrical conductivity, and that the amount of liquid sprayed is limited to 10⁻¹⁰ to 10⁻⁹ m³/sec, thereby making it difficult to be applied to mass product processes.

Furthermore, there occurs a problem where according the features of the droplets being sprayed towards a substrate and the conditions of the substrate, the droplets being sprayed may not be shot to the substrate uniformly.

### SUMMARY

Therefore, the purpose of the present disclosure is to resolve the aforementioned problems of prior art, that is to provide a coating system using a spray nozzle capable of controlling the size of droplets to be fine and uniform so as to coat a substrate effectively, and applicable to mass production processes.

In a general aspect, there is provided a coating system using a spray nozzle, the coating system comprising: a support where a substrate is disposed; a spray nozzle injecting liquid that has gone through a primary atomization by collision with gas, towards the substrate; a voltage applier applying voltage to the spray nozzle so that the liquid injected from the spray nozzle includes electric charge, and generating an electric field between the support and the spray nozzle by the voltage applied to the spray nozzle and performing a secondary atomization of the liquid injected from the spray nozzle; and a transferrer transferring at least one of the support and the spray nozzle.

In the general aspect of the coating system, it is desirable that the support is made of conductive material.

In the general aspect of the coating system, it is desirable that the support is provided with a coating layer of non-conductive material on an external surface thereof.

In the general aspect of the coating system, it is desirable that the support receives voltage or is grounded selectively depending on its location.

In the general aspect of the coating system, it is desirable that the coating system further comprises a plasma processor configured to plasma process the substrate; and that the spray nozzle is provided with a substrate plasma processed through the plasma processor.

In the general aspect of the coating system, it is desirable that the plasma processor cleans a surface of the substrate, or processes the surface of the substrate to be hydrophilic or hydrophobic depending on the liquid injected from the spray nozzle.

In the general aspect of the coating system, it is desirable that the plasma processor performs at least one of charging and discharging the substrate, and the spray nozzle is spaced by 500 mm or less from the plasma processor along a transferring path of the substrate.

In the general aspect of the coating system, it is desirable that the transferrer comprises a first transferrer configured to transfer the support; and a second transferrer configured to move the spray nozzle in a direction approaching or distancing from the support.

In the general aspect of the coating system, it is desirable that the coating system further comprises a container accommodating a spray nozzle inside thereof, the container comprising an inlet and outlet for entering/exiting of the substrate.

In the general aspect of the coating system, it is desirable that the the container is provided with a gas channel for injecting nitrogen or inert gas inside thereof or discharging the nitrogen or inert gas.

In the general aspect of the coating system, it is desirable that at least one of a certain gas concentration, temperature and humidity is maintained inside the container.

In the general aspect of the coating system, it is desirable that the coating system further comprises a sensor configured to obtain location information of the support; and a controller configured to receive the location information of the support through the sensor and control operations of at least one of the plasma processor, spray nozzle, voltage applier and transferrer.

In the general aspect of the coating system, it is desirable that the controller comprises: an electric field control module configured to control an intensity of an electric field formed between the spray nozzle and the support by adjusting a voltage amount applied to the spray nozzle; a pressure control module configured to control a pressure of the gas that collides with the liquid in the spray nozzle; a transfer control module configured to control a movement of the transferrer; and a flow rate control module configured to control a flow rate of the liquid injected form the spray nozzle.

In the general aspect of the coating system, it is desirable that the spray nozzle comprises: a liquid injector configured to inject liquid; and a gas injector configured to have the gas collide with ink on an injection path of the liquid so that a primary atomization is performed of the liquid.

In the general aspect of the coating system, it is desirable that the gas vertically collides with a movement path of the ink.

In the general aspect of the coating system, it is desirable that the spray nozzle further comprises a case accommodating the liquid injector and the gas injector inside thereof, and a gas path configured to guide a flow direction of the gas so that the gas injected from the gas injector collides with the liquid on the injection path of the gas.

According to the present disclosure, there is provided a coating system using a spray nozzle capable of coating a surface of a substrate uniformly according to the present disclosure.

In addition, it is possible to apply a process of coating a substrate to mass production processes.

In addition, it is possible to improve a substrate shooting rate of droplets by plasma processing a surface of the substrate according to features of droplets to be coated on the surface of the substrate.

In addition, it is possible to divide a precoated area and an area not coated prior to performing a coating process by plasma processing the area to be coated, in consideration of features of droplets coated on a surface of a substrate.

In addition, it is possible to easily shoot droplets injected from a spray nozzle by charging or discharging a surface of a substrate through a plasma processing.

In addition, it is possible to easily adjust conditions for coating a substrate by closing a spray nozzle.

### BRIEF DESCRIPTION OF THE DRAWINGS

Throughout the drawings and the detailed description, unless otherwise described, the same drawing reference numerals will be understood to refer to the same elements, features, and structures. The relative size and depiction of these elements may be exaggerated for clarity, illustrating, and convenience.

FIG. 1 is a schematic skewed view of a coating system using a spray nozzle according to an exemplary embodiment of the present disclosure.

FIG. 2 is a schematic skewed view of inside a container in a coating system using a spray nozzle according to FIG. 1.

FIG. 3 is a schematic cross-sectional view of two types of spray nozzle used in a coating system using a spray nozzle according to FIG. 1.

FIG. 4 is a schematic conceptual view of a controller in a coating system using a spray nozzle according to FIG. 1.

FIG. 5 is a schematic plane view of inside a container in a coating system using a spray nozzle according to FIG. 1.

FIG. 6 is a schematic view of a substrate plasma processed by a plasma processor in a coating system using a spray nozzle according to FIG. 1.

FIG. 7 is a schematic skewed view of coating a plasma processed substrate through a spray nozzle in a coating system using a spray nozzle according to FIG. 1.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

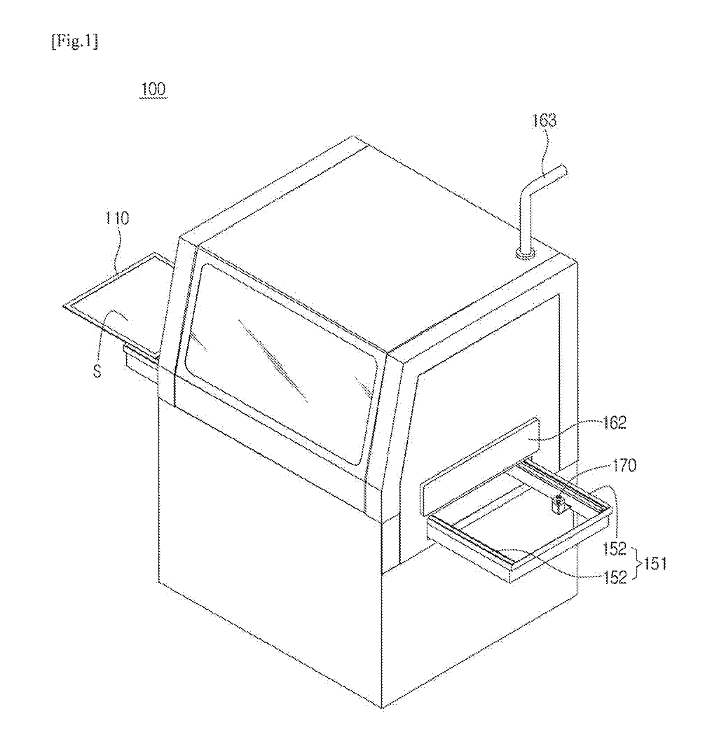

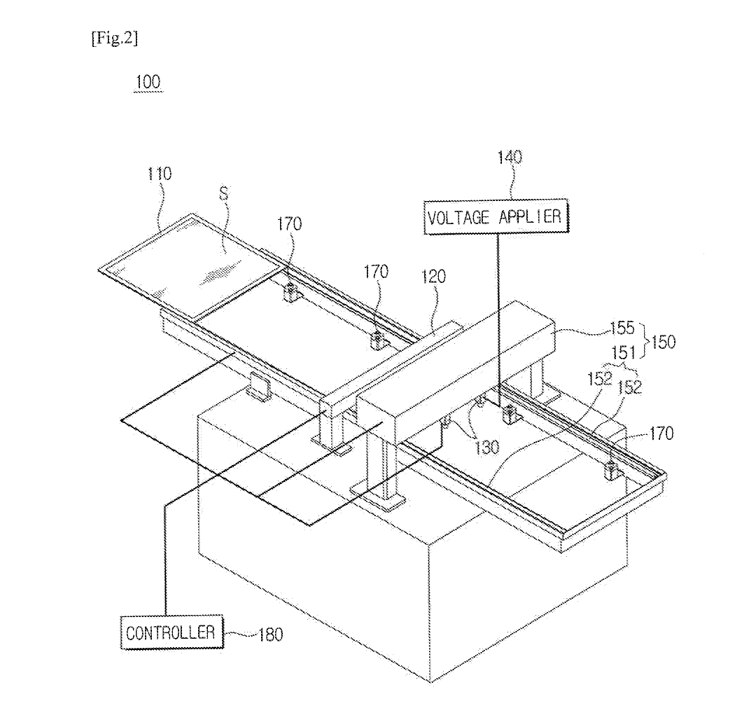

FIG. 1 is a schematic skewed view of a coating system using a spray nozzle according to an exemplary embodiment of the present disclosure, and FIG. 2 is a schematic skewed view of inside a container in a coating system using a spray nozzle according to FIG. 1.

With reference to FIG. 1 or FIG. 2, a coating system using a spray nozzle according to an exemplary embodiment of the present disclosure is capable of coating a substrate with uniformly atomized droplets and improving a substrate shooting rate of atomized droplets by plasma processing a surface of the substrate prior to coating the substrate. Herein, the coating system using a spray nozzle comprises a support 110, plasma processor 120, spray nozzle 130, voltage applier 140, transferrer 150, container 160, sensor 170, and controller 180.

The support 110 is where a substrate S is disposed, the support 110 being provided by a flat panel type material. In an exemplary embodiment of the present disclosure, the support 110 is moveable through a first transferrer 151 that will be explained hereinafter, and guides a movement of the substrate S so as to sequentially process a plasma processing and coating process.

Meanwhile, the support 110 according to an exemplary embodiment of the present disclosure receives voltage or is grounded according to each process of processing the substrate, and for this purpose, the support 110 is provided by a conductive material.

In addition, in order to prevent direct affect on the substrate S, an outer surface that contacts the substrate S is preferably provided with a coating layer 111 of nonconductive material.

Meanwhile, according to an exemplary embodiment of the present disclosure, in an example of voltage being applied to the support 110, as a polarity other than the polarity of plasma is applied to the support 110, the plasma may move towards the substrate S when a surface of the substrate S is plasma processed as it passes the plasma processor 120.

In addition, in an example of the support 110 being grounded, the support 110 is grounded so that plasma is stably formed when a surface of the substrate S is plasma processed as it passes the plasma processor 120.

Furthermore, in another example of the support 110 being grounded, a potential difference may be generated between a spray nozzle 130 and a support 110 so as to form a strong electric field between the spray nozzle 130 and the support 110 when the substrate S is coated as it passes the spray nozzle 130.

Of course, there is no limitation to the aforementioned, and thus if necessary, voltage may be applied to the support 110 or the support 110 may be grounded.

The plasma processor 120 is configured to plasma process an outer surface of the substrate S being transferred through a first transferrer 151 that will be explained hereinafter.

According to an exemplary embodiment of the present disclosure, the plasma processor 120 may clean a coated surface of the substrate S, or process the surface of the substrate S to be coated to be hydrophilic or hydrophobic.

Herein, the hydrophilic or hydrophobic features are determined in consideration of the liquid used in a spray nozzle 130 that will be explained hereinafter.

That is, if the liquid used in the spray nozzle 130 is hydrophilic, an outer surface of the substrate S is plasma processed to be hydrophilic so that the liquid can be effectively shot to the outer surface of the substrate S. On the contrary, if the liquid used in the spray nozzle 130 is hydrophobic, the outer surface of the substrate S is plasma processed to be hydrophobic.

Furthermore, a portion of the substrate S may be processed to be hydrophilic while the remaining portion of the substrate S is processed to be hydrophobic. That is, in a case of coating an outer surface of the substrate S to have a certain pattern, a certain area of an outer surface of the substrate S may be plasma processed to have same features as the liquid, while the remaining area besides the certain area of the outer surface of the substrate S is plasma processed to have different features from the liquid, thereby coating the substrate such that the liquid is concentrated on the certain area.

In addition, in an exemplary embodiment of the present disclosure, the plasma processor 120 may perform a process of charging or discharging the substrate S. Herein, a discharging of the substrate S is performed when charges on the substrate S are distributed non-uniformly, whereas a charging of the substrate S is performed when charges on the substrate S are distributed uniformly.

That is, by discharging or charging the substrate S through the plasma processor 120, it is possible to shoot atomized droplets from the spray nozzle 130 that will be explained hereinafter even more effectively.

Meanwhile, as aforementioned, in the present exemplary embodiment of the present disclosure, the substrate S is processed to be hydrophilic or hydrophobic or discharged or charged through the plasma processor 120, but without limitation.

In addition, in an exemplary embodiment of the present disclosure, the plasma processor 120 may be an atmospheric-pressure plasma, but without limitation.

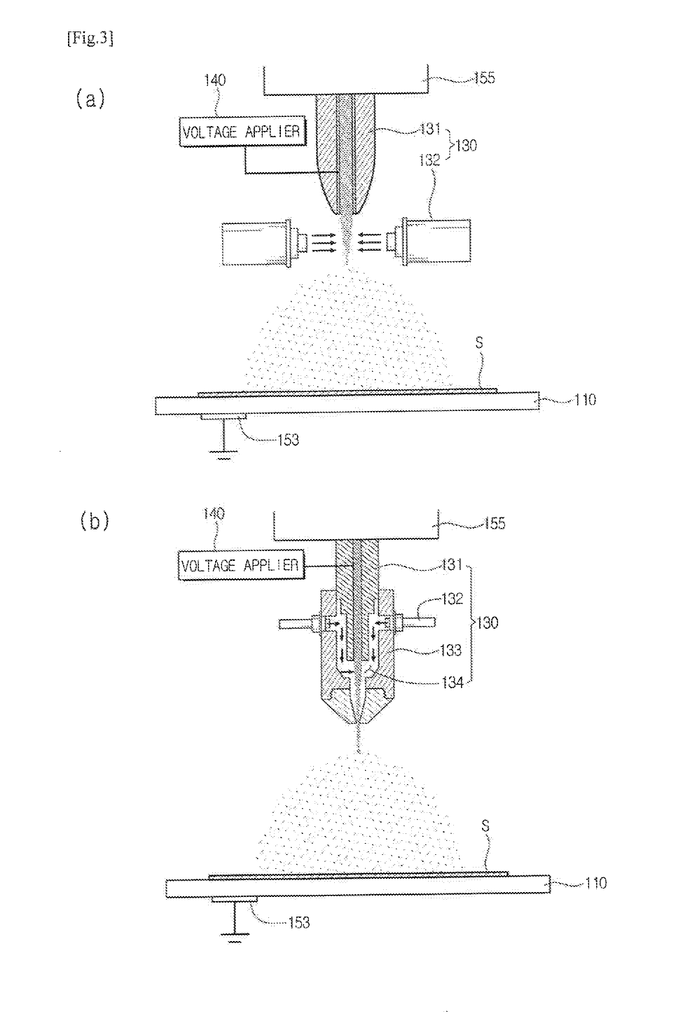

FIG. 3 is a schematic cross-sectional view of two types of spray nozzle used in a coating system using a spray nozzle according to FIG. 1.

With reference to FIG. 3, the spray nozzle 130 receives the substrate S plasma processed through the aforementioned plasma processor 120, and injects towards the substrate the droplets that have gone through primary atomization by colliding with gas. Herein, the spray nozzle 130 comprises a liquid injector 131 and gas injector 132.

The liquid injector 131 is a path where ink flows, and it also injects the ink towards the plasma processed substrate S.

The gas injector 132 is configured to inject gas, and the gas injected from the gas injector 132 vertically collides with an injection path of the ink, thereby performing a primary atomization of the liquid.

Herein, for a primary atomization of the ink, collision of the gas and ink is a very important factor, and in order to stably atomize the ink, the gas must collide vertically with the injection path of the ink.

That is, if the gas fails to vertically collide with the injection path of the ink, the gas may have an effect in the injection direction of the ink or in the opposition direction thereof. When collision of the gas and ink applies a force in the injection direction of the ink, the atomized ink may collide with the substrate S at an excessive speed thereby causing the ink to rebound. And when collision of the gas and ink applies a force in the opposite direction of the injection direction of the ink, the injection of the ink may be interrupted by the gas, thereby having a negative effect on the injection speed or injection flow rate of the ink.

Therefore, in order to prevent these problems, it is preferable without limitation that the gas vertically collides with the injection path of the ink, but these problems may be resolved instead by adjusting the injection speed of the ink.

Meanwhile, as illustrated in FIG. 3(a), the liquid injected through the liquid injector 131 and the gas injected through the gas injector 132 may collide with each other in an area between the spray nozzle 130 and the support 110.

In such a case, in order to minimize the effect of other factors when the liquid collides with the gas, it is desirable that an area that is coated by the spray nozzle 130 is provided with an additional chamber and be closed.

In addition, it is desirable that there is further provided a case 133 that accommodates a liquid injector 131 and gas injector 132 inside thereof so that the collision of the liquid and the gas can be made in a sealed space as illustrated in FIG. 3(b), thereby the spray nozzle 130 injecting liquid that has been almost atomized or preferably completely atomized.

Herein, inside the case, there may be further provided without limitation a gas path 134 where the gas injected from the gas injector 132 flows and that guides the flowing direction of the gas so that the gas vertically collides with the injection path of the liquid.

The voltage applier 140 applies voltage to the spray nozzle 130 so that the liquid injected from the spray nozzle 130 can include electric charge, and creates an electric field between the spray nozzle 130 and the support 110 by the voltage applied to the spray nozzle to perform a secondary atomization of the liquid injected from the spray nozzle 130 through the electric field.

Meanwhile, in an exemplary embodiment of the present disclosure, the spray nozzle 130 is situated, without limitation, to be close to the plasma processor 120, and the spray nozzle 130 and the plasma processor 120 are spaced from each other by a distance of 500 mm or below so that the liquid having electric charge when the substrate S is charged or discharged through the plasma processor 120 can be easily shot to the substrate S.

That is, it is desirable that the spray nozzle 130 and the plasma processor 120 are close to each other so as to prevent the electric charge on the charged or discharged substrate S dissipating before the liquid is shot to the substrate S, and in an exemplary embodiment of the present disclosure, the spray nozzle 130 and the plasma processor 120 are spaced from each other by 500 mm or below.

Meanwhile, when voltage is applied to the liquid injector 131 through the voltage applier 140, the liquid injected to the substrate S through the liquid injector 131 would include electric charge by the voltage applied from the voltage applier 140, and a potential difference would be generated between the support 110 and the spray nozzle 130 thereby forming an electric field for performing a secondary atomization of the liquid that has gone through a primary atomization.

By sequentially atomizing liquid through collision with gas and through an electric field as aforementioned, it is possible to form fine droplets of a uniform size and inject a large amount of liquid. Furthermore, by guiding the atomized liquid to be injected towards the substrate S using the electric field, it is possible to prevent the droplets from rebounding and reduce the amount of consumption of the material.

The transferrer 150 transfers at least one of the aforementioned support 110 and spray nozzle 130. The transferrer 150 comprises a first transferrer 151 configured to transfer the support 110 and a second transferrer 155 configured to transfer the spray nozzle 130.

The first transferrer 151 transfers the support 110, and in an exemplary embodiment of the present disclosure, the first transferrer 151 comprises a rail 152 and an electrode 153.

The rail 152 consists of a pair of rail members facing each other. The support 110 is mounted onto an upper side of the rail members so that the support 110 can slide along the rail 152.

In addition, besides transferring the support 110 along the rail 152, the first transferrer 151 may be provided, but without limitation, such that it rotates the support 110 on the upper side of the rail 152 or transfer the support 110 on a virtual plane that is parallel to the support 110.

The electrode 153 is provided between the pair of 152. In response to reaching a certain position of the support 110, the electrode 153 contacts the support 110 and applies voltage to the support or grounds the support 110.

Herein, the electrode 153 has a shape of a roll, a portion of the roll being provided with voltage while the remaining portion being grounded. By rotation, the electrode 153 selectively applies voltage to the support 110 or grounds the support 110.

Meanwhile, the electrode 153 may have a shape of a spring, which applies voltage to the support 110 or grounds the support 110 as it contacts or is distanced from the support 110 by elasticity.

The second transferrer 155 is connected to the spray nozzle 130 to transfer the spray nozzle 130 in a direction either approaching or distancing from the support 110 or in a direction parallel to the support 110.

That is, defining the directions parallel to the support 110 are x and y axis directions, and the direction approaching or distancing from the support 110 is z axis direction, the second transferrer 155 transfers the spray nozzle 130 in at least one direction of x, y, and z axis directions.

Meanwhile, the transferrer 150 may further comprise, without limitation, a third transferrer (not illustrated) configured to move the plasma processor 120 in a direction approaching or distancing from the support 110 or in a direction parallel to the support 110.

The container 160 accommodates the plasma processor 120 and spray nozzle 130 inside thereof, and isolates the substrate S from outside during processing so as to maintain certain processing conditions.

In exemplary embodiment of the present disclosure, there is formed an inlet 161 to which the substrate S is provided and an outlet 162 to which the substrate S is output, and the first transferrer 151 is extended towards the inlet 161 and the outlet 162.

In addition, the inlet 161 and the outlet 162 are provided such that they may be open/closed to close the inside of the container 160 during plasma processing and coating processing.

Furthermore, the container 160 may be provided with a gas channel 163 through which nitrogen or inert gas may be injected inside the container 160.

Meanwhile, for an effective coating process, a certain gas concentration, humidity and temperature may be maintained, without limitation, inside the container 160.

In other words, it is possible to measure the gas concentration, humidity and temperature inside the container 160, and adjust the opening time etc. of the gas channel 163 to maintain the optimal gas concentration, humidity and temperature inside the container 160 based on the measurement results.

The sensor 170 measures location information of the support 110.

In an exemplary embodiment of the present disclosure, the sensor 170 is provided in plural number, each spaced from one another along the rail 152. The sensor 170 divides the location of the support 110 into an inlet section, a section being affected by the plasma processor 120, a section being affected by the spray nozzle 130, and an outlet section, and measures where the support 110 is located.

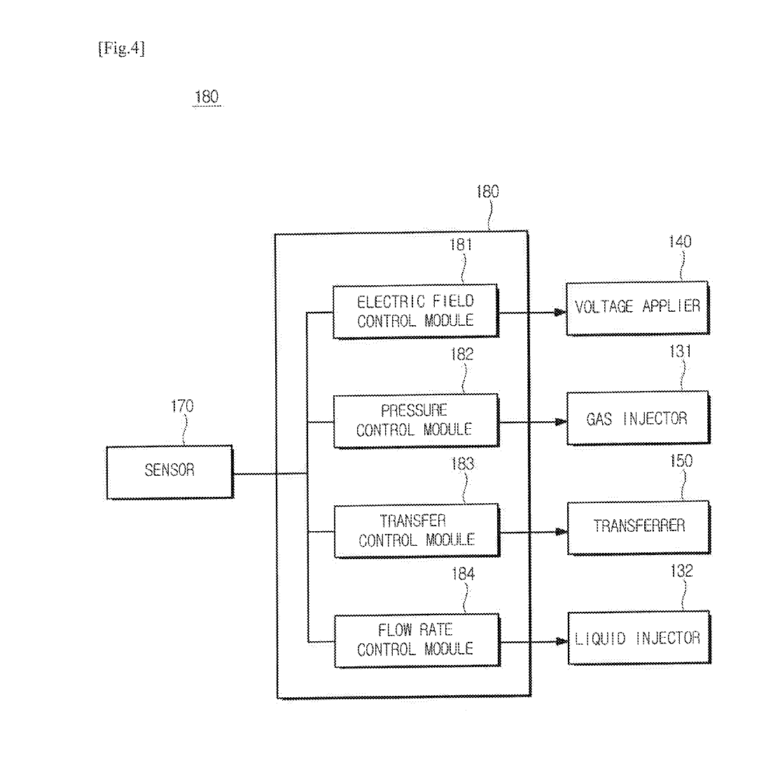

FIG. 4 is a schematic conceptual view of a controller in a coating system using a spray nozzle according to FIG. 1.

The controller 180 receives location information of the support 110 from the aforementioned sensor 170, and controls operations of at least one of the plasma processor 120, spray nozzle 130, voltage applier 140 and transferrer 150. The controller 180 comprises an electric field control module 181, pressure control module 182, transfer control module 183, and flow rate control module 184.

The electric field control module 181 adjusts the voltage applied to the liquid injector 131 through the voltage applier 140 to control the intensity of the electric field generated between the support 110 and the spray nozzle 130.

As aforementioned, the intensity of the electric field is related to the secondary atomization of liquid, and thus it is possible to control the speed of the secondary atomization of liquid by adjusting the intensity of the electric field by the electric field control module 181.

The pressure control module 182 adjusts the pressure of the gas supplied to the gas injector 132. As aforementioned, the gas performs a primary atomization of liquid by colliding with the liquid being injected, and thus it is possible to control the primary atomization of the liquid by adjusting the pressure of the gas flowing along the gas injector 132.

The transfer control module 183 controls the movement of the transferrer 150 so as to control the location and transferring speed of the support 110, and the location and transferring speed of the spray nozzle 130.

That is, the transfer control module 183 may control, without limitation, the first transferrer 151 so that the substrate S disposed on the support 110 performs a certain process, and may control, without limitation, the second transferrer 152 to change the initial injection location of the spray nozzle 130.

The spray nozzle 130 may be transferred, without limitation, even when the liquid is being injected, and the transferring speed may be controlled, without limitation, such that it does not affect the injection state of the liquid.

The flow rate control module 184 controls the flow rate of the liquid injected from the spray nozzle 130 by adjusting the flow rate of the liquid supplied to the liquid injector 131.

That is, the liquid density and diameter of the liquid injector 131 being the same, the injection speed of the liquid is proportionate to the mass flow rate or volumetric flow rate of the liquid, and thus it is possible to control the injection speed of the liquid by adjusting the mass flow rate or volumetric flow rate of the liquid.

Herein, the injection speed of the liquid affects the time it takes for the injected liquid to arrive at the substrate S, and if this time is significantly short, the liquid would arrive at the substrate S without having gone through a sufficient secondary atomization, thereby increasing the roughness and non-uniformity of the coating surface of the substrate S. Therefore, the injection speed is controlled by the flow rate control module 184.

Hereinbelow is explanation on operations of an exemplary embodiment of a coating system using the aforementioned spray nozzle.

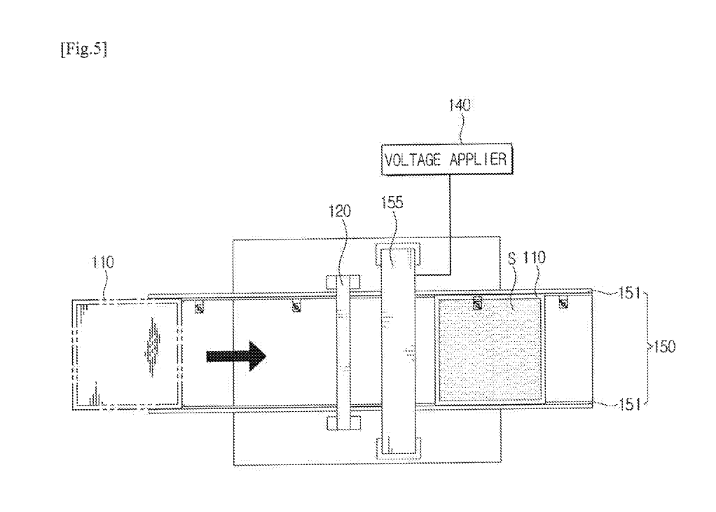

FIG. 5 is a schematic plane view of inside a container in a coating system using a spray nozzle according to FIG. 1.

Hereinbelow is explanation on operations of a coating system using a spray nozzle according to an exemplary embodiment of the present disclosure 100 based on the transferring direction of the substrate S with reference to FIG. 5.

The substrate S is fixated to the support 110 disposed outside the container 160, and then the support 110 is moved inside the container 160 through the first transferrer 151.

Herein, when the support 110 moves inside the container 160 through the inlet 161 of the container 160, the inlet 161 closes, and the support 110 moves to a processing area of the plasma processor 120.

Meanwhile, when the support 110 arrives at a lower side of the plasma processor 120, the controller 180, having acknowledged the location of the support 110 through the sensor 170, controls operations of the plasma processor 120 to output plasma towards the support, more particularly towards the substrate S.

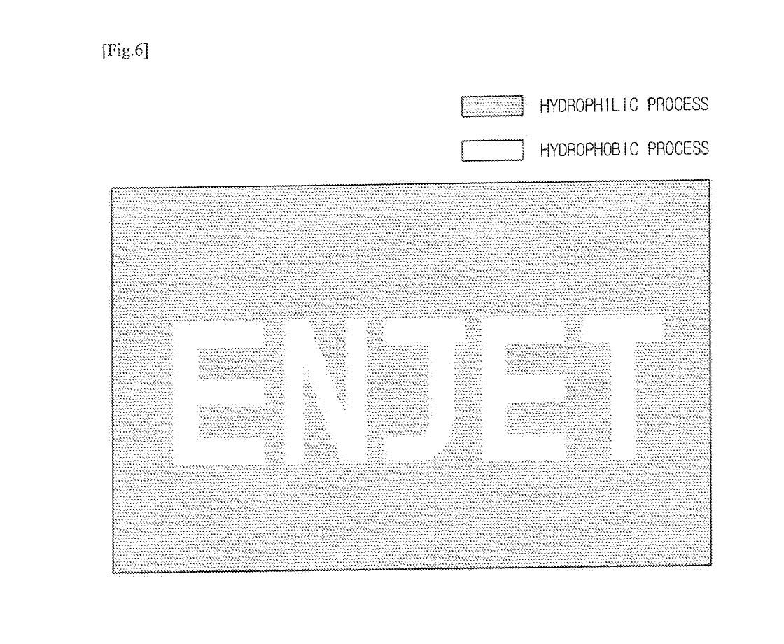

FIG. 6 is a schematic view of a substrate plasma processed by a plasma processor in a coating system using a spray nozzle according to FIG. 1.

With reference to FIG. 6, by the plasma being output towards the substrate S, the substrate S is processed to be hydrophilic or hydrophobic, or charged or discharged. And to improve the effectiveness of the processings, the support 110 is provided with voltage or is grounded by the electrode 153.

In an exemplary embodiment of the present disclosure, in order to coat the substrate S with letters ‘ENJET’, the letter part of ‘ENJET’ is processed to be hydrophobic while the background part is processed to be hydrophilic through the plasma processor 120.

Meanwhile, the plasma processed substrate S moves to the lower side of the spray nozzle 130 by the first transferrer 151, the sensor acknowledges the location of the support 110, and the controller 180 controls the operations of the spray nozzle 130.

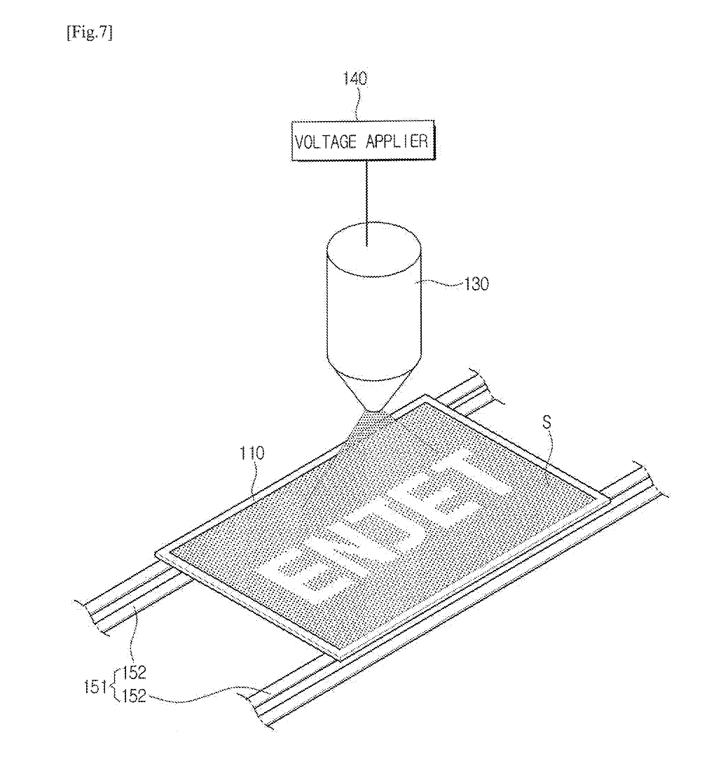

FIG. 7 is a schematic skewed view of coating a plasma processed substrate through a spray nozzle in a coating system using a spray nozzle according to FIG. 1.

With reference to FIG. 7, the spray nozzle 130 injects liquid towards the plasma processed substrate S, the liquid injected towards the substrate S collides with the gas injected from the gas injector 131 between the support 110 and the spray nozzle 130, and thus a primary atomization of the liquid occurs. By such collision with the gas, the liquid surface becomes unstable, and due to this instability of the liquid surface, a secondary atomization of the liquid by the electric field occurs actively even when the nonpolarity or electrical conductivity of the liquid is extremely low.

Herein, in order to prevent the collision with the gas affecting the injection speed of the liquid, the gas collides vertically, without limitation, with the gas.

The liquid that has been unstabilized while going through a primary atomization by collision with the gas goes through a secondary atomization by the electric field that occurs between the spray nozzle 130 and the support 110. Since the liquid has already gone through the primary atomization by collision with the gas, the flow rate of the liquid that can be atomized increases significantly than in the case of atomizing the liquid simply using the electric field only, and this leads the increase of processing speed.

Discharging ink in such a method achieves both the advantage of a gas assisted atomizer, that is increase of ink spray amount, and the advantage of electric spraying, that is creation of fine and uniform droplets. Furthermore, guiding the path of the droplets that have gone through a secondary atomization by the electric field between the spray nozzle 130 and the support 110 may resolve all the problems including the rebounding of droplets and increase of ink consumption. Moreover, since it is not a process wherein the liquid surface is changed to taylor-cone on the nozzle and spray is produced at the end, it is possible to perform a secondary atomization on ink made of low electric conductivity material or nonconductive (dielectric) material regardless of the polarity of the ink. Such a principle is based on the mathematical equation below.

$${{f}^{->}}_{e} = {ρ}_{e} {E}^{->} - \frac{1}{2} \vert {E}^{->} \vert {}^{2} {∇}_{ɛ} + ∇ ( \frac{1}{2} ( ɛ - {ɛ}_{0} ) {\vert {E}^{->} \vert}^{2} )$$

Herein, ₑ indicates free electron on liquid surface, e dielectric constant, e₀ dielectric constant in vacuum, and E electric field.

Herein, in the case of dielectric liquid, in the above equation, the second and third forces will be applied, while in the case of a non-polar liquid, in the above equation, an electric force of the second section will be applied. This is called a dielectrophoretic force. Herein, since there exists only an electric force that acts on the vertical direction of the liquid surface and not in the direction tangent to the liquid surface, there won't be formed a liquid surface having a conical shape called the taylor-cone, and thus atomizing the liquid will not be easy with only an electric field.

However, by making droplets unstable at the same time of performing a primary atomization by inducing collision with gas as in a spray nozzle according to a first exemplary embodiment of the present disclosure 130, a secondary atomization may occur in spite of a weak dielectrophoretic force.

Accordingly, by utilizing a spray nozzle according to an exemplary embodiment of the present disclosure 130, it is possible to easily induce atomization of even nonconductive liquid regardless of the polarity of the liquid.

As aforementioned, the liquid that has gone through the secondary atomization flows towards the substrate S.

Herein, depending on the features of the atomized liquid, more particularly depending on whether the atomized liquid is hydrophilic or hydrophobic, coating of the atomized liquid may be concentrated on letters ‘ENJET’, or on the background part of ‘ENJET’.

Since the liquid used in an exemplary embodiment of the present disclosure is hydrophobic, the substrate S is coated and a pattern is formed such that the coating of the atomized liquid is concentrated on the letters ‘ENJET’.

Meanwhile, when the substrate S which has completed being coated through the spray nozzle 130 is transferred to the outlet 162, the sensor 170 measures the location the substrate S and opens the outlet 162, and transfers the substrate S outside the container 160.

A number of examples have been described above. Nevertheless, it will be understood that various modifications may be made. For example, suitable results may be achieved if the described techniques are performed in a different order and/or if components in a described system, architecture, device, or circuit are combined in a different matter and/or replaced or supplemented by other components or their equivalents. Accordingly, other implementations are within the scope of the following claims.

### DESCRIPTION OF REFERENCE NUMERALS

100: COATING SYSTEM USING SPRAY NOZZLE
S: SUBSTRATE
110: SUPPORT
120: PLASMA PROCESSOR
130: SPRAY NOZZLE
140: VOLTAGE APPLIER
150: TRANSFERRER
160: CONTAINER
170: SENSOR
180: CONTROLLER

What is claimed is:

1. A coating system using a spray nozzle, the coating system comprising:
a support where a substrate is disposed;
a spray nozzle injecting liquid that has gone through a primary atomization by collision with gas, towards the substrate;
a voltage applier applying voltage to the spray nozzle so that the liquid injected from the spray nozzle includes electric charge, and generating an electric field between the support and the spray nozzle by the voltage applied to the spray nozzle and performing a secondary atomization of the liquid injected from the spray nozzle; and
a transferrer transferring at least one of the support and the spray nozzle.

2. The coating system according to claim 1,
wherein the support is made of conductive material.

3. The coating system according to claim 2,
wherein the support is provided with a coating layer of non-conductive material on an external surface thereof.

4. The coating system according to claim 2,
wherein the support receives voltage or is grounded selectively depending on its location.

5. The coating system according to claim 3,
wherein the support receives voltage or is grounded selectively depending on its location.

6. The coating system according to claim 1,
further comprising a plasma processor configured to plasma process the substrate;
wherein the spray nozzle is provided with a substrate plasma processed through the plasma processor.

7. The coating system according to claim 6,
wherein the plasma processor cleans a surface of the substrate, or processes the surface of the substrate to be hydrophilic or hydrophobic depending on the liquid injected from the spray nozzle.

8. The coating system according to claim 6,
wherein the plasma processor performs at least one of charging and discharging the substrate, and
the spray nozzle is spaced by 500 mm or less from the plasma processor along a transferring path of the substrate.

9. The coating system according to claim 1,
wherein the transferrer comprises a first transferrer configured to transfer the support; and
a second transferrer configured to move the spray nozzle in a direction approaching or distancing from the support.

10. The coating system according to claim 1,
further comprising a container accommodating a spray nozzle inside thereof, the container comprising an inlet and outlet for entering/exiting of the substrate.

11. The coating system according to claim 10,
wherein the container is provided with a gas channel for injecting nitrogen or inert gas inside thereof or discharging the nitrogen or inert gas.

12. The coating system according to claim 11,
wherein at least one of a certain gas concentration, temperature and humidity is maintained inside the container.

13. The coating system according to claim 6,
further comprising a sensor configured to obtain location information of the support; and
a controller configured to receive the location information of the support through the sensor and control operations of at least one of the plasma processor, spray nozzle, voltage applier and transferrer.

14. The coating system according to claim 13,
wherein the controller comprises:
an electric field control module configured to control an intensity of an electric field formed between the spray nozzle and the support by adjusting a voltage amount applied to the spray nozzle;
a pressure control module configured to control a pressure of the gas that collides with the liquid in the spray nozzle;
a transfer control module configured to control a movement of the transferrer; and
a flow rate control module configured to control a flow rate of the liquid injected form the spray nozzle.

15. The coating system according to claim 1,
wherein the spray nozzle comprises:
a liquid injector configured to inject liquid; and
a gas injector configured to have the gas collide with ink on an injection path of the liquid so that a primary atomization is performed of the liquid.

16. The coating system according to claim 15,
wherein the gas vertically collides with a movement path of the ink.

17. The coating system according to claim 15,
wherein the spray nozzle further comprises a case accommodating the liquid injector and the gas injector inside thereof, and
a gas path configured to guide a flow direction of the gas so that the gas injected from the gas injector collides with the liquid on the injection path of the gas.
